(19) United States
(12) Patent Application Publication
(10) Pub. No.: US 2026/0125262 A1
(43) Pub. Date: May 7, 2026

(54) METHOD FOR MANUFACTURING A MICROELECTROMECHANICAL SYSTEM MIRROR DEVICE, MANUFACTURING APPARATUS, SET OF MIRROR DEVICES AND WAFER

(71) Applicant: Infineon Technologies AG, Neubiberg (DE)

(72) Inventors: Dirk MEINHOLD, Dresden (DE); Stephan Gerhard ALBERT, München (DE); André BROCKMEIER, Villach (AT); Markus BAINSCHAB, Villach (AT)

(21) Appl. No.: 19/360,569

(22) Filed: Oct. 16, 2025

(30) Foreign Application Priority Data
Nov. 5, 2024 (DE) 102024132108.3

(51) Int. Cl. B81C 1/00; B81B 7/04; B81C 99/00; G02B 26/08

(52) U.S. Cl. CPC B81C 1/00404; B81B 7/04; B81C 99/004; G02B 26/0833; B81B 2201/042; B81C 2201/0156

(57) ABSTRACT

According to an implementation, a method for manufacturing a microelectromechanical system mirror device is provided. A mirror portion of the mirror device is rotatable about a first axis having an associated first resonance frequency and a second axis different from the first axis and having an associated second resonance frequency. The method includes estimating a deviation of a first geometry parameter of the mirror device from a reference value, and adjusting a manufacturing step for the mirror device to modify a second geometry parameter of the mirror device different from the first geometry parameter such that a variation of a frequency ratio between the first resonance frequency and the second resonance frequency caused by the deviation of the first geometry parameter and the modifying of the second geometry parameter is below a predefined threshold.

### CROSS-REFERENCE TO RELATED APPLICATION

This application claims priority to Germany Patent Application No. 102024132108.3 filed on Nov. 5, 2024, the content of which is incorporated by reference herein in its entirety.

### TECHNICAL FIELD

The present application relates to a method for manufacturing a microelectromechanical system (MEMS) mirror device, a corresponding manufacturing apparatus, a set of corresponding mirror devices and a wafer including a plurality of mirror devices.

### BACKGROUND

A laser beam scanner (LBS) is a device where a laser beam is scanned across an area by using one or more adjustable mirrors to deflect the laser beam. For example, such laser beam scanners may be used for display applications, where the laser beam is scanned across a screen. One type of laser beam scanners are two axes resonant Lissajous laser beam scanners. Here, a mirror is rotatable about two axes, each having an associated resonance frequency. The axis having a higher resonance frequency is also referred to as fast axis, and the axis having a lower resonance frequency is referred to as slow axis. A schematic view of a corresponding mirror device having a gimbal structure is shown in FIG. 1.

Here, a mirror 11 is suspended rotatable about a first axis 12 in a frame 13. Frame 13 is suspended to be rotatable about a second axis 14 within a frame 15. Frame 15 in operation is stationary. In mirror device 10, usually first axis 12 is associated with a higher resonance frequency than second axis 14, as around axis 14 not only mirror 11, but also frame 13 and axis 12, rotate together, e.g., there is a higher mass. However, the resonance frequencies may also be affected by the design of the axis, for example their torsion spring constants.

Mirror device 10 may be implemented as a microelectromechanical system (MEMS), for example by processing a silicon wafer accordingly with standard techniques for manufacturing such MEMS, including lithography, etching, layer deposition and the like.

In addition to the elements schematically shown in FIG. 10, such mirror devices may also have drive units for exciting the mirror device 10 to rotate about first axis 12 and second axis 14 with the corresponding resonance frequencies. With an appropriate design, a laser impinging on mirror 11 scans a desired area.

To provide, for example, for display applications, a physically satisfying image, the ratio between the resonance frequencies of the fast and slow axis has to be in a small range around a target value. However, for example, due to process variations deviations from such a target value may be possible.

### SUMMARY

According to an implementation, a method for manufacturing a microelectromechanical system mirror device is provided. A mirror portion of the mirror device is rotatable about a first axis having an associated first resonance frequency and a second axis different from the first axis and having an associated second resonance frequency.

The method comprises estimating a deviation of a first geometry parameter of the mirror device from a reference value, and adjusting a manufacturing step for the mirror device to modify a second geometry parameter of the mirror device different from the first geometry parameter such that a variation of a frequency ratio between the first resonance frequency and the second resonance frequency caused by the deviation of the first geometry parameter and the modifying of the second geometry parameter is below a predefined threshold.

According to another implementation, a corresponding manufacturing apparatus is provided, which is configured to perform a plurality of manufacturing steps to manufacture the mirror device. The apparatus is configured to estimate a deviation of a first geometry parameter of the mirror device from a reference value and adjust a manufacturing step of the plurality of manufacturing steps to modify a second geometry parameter as described above.

In another implementation, a set of microelectromechanical system mirror devices of the same type is provided, wherein a mirror portion of each mirror device of the set is rotatable about a respective first axis having an associated first resonance frequency and a respective second axis different from the first axis and having an associated second resonance frequency. The set comprises a first mirror device and a second mirror device. A first geometry parameter of the first mirror device differs from the first geometry parameter of a second mirror device by a first difference. Furthermore, a second geometry parameter of a second mirror device differs from the second geometry parameter of the second mirror device by a second difference. A difference between a first ratio between the first and second resonance frequency of the first mirror device and a second ratio of the first and second resonance frequencies of the second mirror device of the second mirror device caused by the first difference alone is above 1% and is compensated by the second difference to be below 1%.

Furthermore, a wafer is provided comprising a first microelectromechanical system mirror device at a first side and a second microelectromechanical system mirror device at a second side. A mirror portion of each of the first and second mirror devices is rotatable about a respective first axis having an associated first resonance frequency and a respective second axis different from the first axis and having an associated second resonance frequency. A first geometry parameter of the first mirror device differs from the first geometry parameter of a second mirror device by a first difference, and a second geometry parameter of a first mirror device differs from the second geometry parameter of the second mirror device by a second mirror device by a second difference. A difference between a first ratio between the first and second resonance frequencies of the first mirror device and a second ratio of the first and second resonance frequencies of the second frequencies of the second mirror device caused by the first difference alone is above 1% and is compensated by the second difference to be below 1%.

The above summary is merely intended to give a brief overview over some implementations and is not to be construed as limiting in any way.

### BRIEF DESCRIPTION OF THE DRAWINGS

FIG. 1 is a schematic diagram of a mirror device usable in some implementations.

FIG. 2 is a flowchart of a manufacturing method according to some implementations.

FIG. 3 is a diagram of a manufacturing apparatus according to an implementation.

FIGS. 4A-4C show a microelectromechanical system mirror device according to some implementations, where FIG. 4A shows a side view, FIG. 4B shows a top view and FIG. 4C shows a bottom view.

FIG. 5 illustrates a device model used in some implementations.

FIG. 6 illustrates a wafer according to some implementations.

FIGS. 7-9 are cross-sectional views of mirror devices in different stages of manufacturing for illustrating various implementations.

### DETAILED DESCRIPTION

In the following various implementations will be described in detail referring to the attached drawings. These implementations are given by way of example only and are not to be construed as limiting.

Details, variations or modifications described for one of the implementations are also applicable to other implementations and will therefore not be described repeatedly. Features from different implementations may be combined to form further implementations.

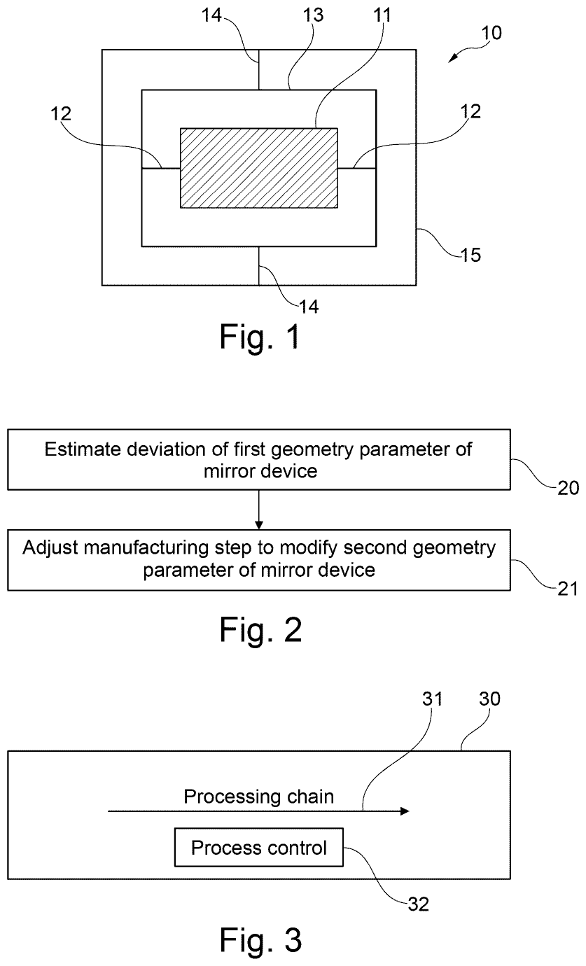

Implementations described herein generally relate to mirror devices of the general type described with respect to FIG. 1, e.g., microelectromechanical system mirror devices (shortly referred to as mirror devices herein) where a mirror is rotatable about a first axis and a second axis different from the first axis, where the first axis has an associated first resonance frequency, and the second axis has an associated second resonance frequency.

FIG. 2 is a flowchart illustrating a method for manufacturing a mirror device according to an implementation. The method of FIG. 2 may be performed in the context of an overall manufacturing process of the mirror device, which overall process may comprise manufacturing steps like lithography steps, etching steps, layer deposition steps (e.g., epitaxial layer deposition, metal layer deposition, dielectric layer deposition)or any other steps of conventional semiconductor processing. In other words, the method described herein is a modification to conventional manufacturing methods, and apart from the described aspects and features of the manufacturing process, the manufacturing process may be implemented in a conventional manner.

At 20, the method comprises estimating a deviation of a first geometry parameter of a mirror device from a reference value. A geometry parameter, as used herein, refers to any parameter describing the geometry of any feature of the mirror device during any stage of the manufacturing process. Such geometry parameters may for example include layer thicknesses, length or width of features, critical dimensions or the like. Examples will be given further below. The reference value may for example be a target value of a design of the mirror device, or a value of the first geometry parameter for another mirror device. For example, the deviation may also be a deviation of the first geometry parameter of a mirror device closer to the edge of a wafer on which the mirror devices are manufactured compared to a mirror device at or near the center of the wafer. In this case, the first geometry parameter of the mirror device at or near the center of the wafer may serve as the reference value.

The estimation of the deviation may include a measurement. In some instances, the measurement may be performed directly on the mirror device (inline measurement during production). In other implementations, the measurement may be made on a different mirror device of the same type. For example, the first geometry parameter may be measured on a test wafer for production, and then a deviation determined based on this measurement may be used as assumed (estimated) deviation for the mirror device.

The first geometry parameter influences the first resonance frequency, the second resonance frequency or both. For example, layer thicknesses or widths of features may influence the mass to be rotated(for example the mass associated with mirror 11 of FIG. 11 or frame 13 of FIG. 1) and therefore the resonance frequencies. The first geometry parameter may also influence spring constants of torsion elements or the like, which in turn also influence the resonance frequencies. By influencing the resonance frequencies, also the ratio of the first resonance frequency to the second resonance frequency may be shifted.

As explained in the introductory portion, for applications like imaging applications it is important that this ratio stays closely within a range, for example within 1% of a target value. However, such deviations of the first geometry parameter, which may for example be caused by processing variations, in some cases may cause a shift of the resonance frequency ratio larger than a predefined threshold, for example larger than 1%.

To at least partially compensate this, at 21 the method comprises adjusting a manufacturing step to modify a second geometry parameter of the mirror device different from the first geometry parameter. The modification of the second geometry parameter also influences the ratio between the first and second resonance frequencies, and a is selected such that a shift of the ratio caused by the deviation estimated at 20 is at least partially compensated. Specific examples will be given below.

The adjusted manufacturing step may be a manufacturing step occurring after a manufacturing step determining the first geometry parameter. For example, if the first geometry parameter is a thickness of a certain layer, the adjusted manufacturing step at 21 may be a step patterning this layer, or a step processing other parts of the mirror device. The adjusted manufacturing step may include a lithography step. In some implementations, as will be explained below adjusting the manufacturing step may include modifying a mask for the lithography, for example modifying dimensions of the mask, which in turn modifies the second geometry parameter. In other implementations, adjusting the manufacturing step may comprise adjusting an irradiation dose of radiation (for example light or electron beam) used during lithography. Also by adjusting the irradiation dose, dimensions like critical dimensions of structures manufactured may be modified, thus modifying the second geometry parameter.

Such a lithography step modification may require no additional processing steps and nevertheless may help to ensure that a variation of the ratio between the first and second resonance frequencies compared to a target ratio remains below a threshold, for example below 1%.

FIG. 3 is a diagram of a manufacturing apparatus 30 according to an implementation. Apparatus 30 comprises a processing chain 31 which includes processing machines for various processing steps like etching, layer deposition, lithography like optical lithography or electron beam lithography, metallization or any other processing which is used for forming microelectromechanical systems, for example on silicon wafers. Note that processing machines may also be used several times within processing chain 31. Furthermore, apparatus 30 includes a process control device 32. Process control device 32 may for example be implemented as a unitary device controlling the whole process flow, separate devices controlling individual manufacturing steps or a hierarchy of process control devices. Process control device 32 may be implemented using microcontrollers, computers or similar controllers. Besides conventional process control, process control device 32 also supports implementing of the method of FIG. 2, for example by obtaining measurement data (for example in-line measurements) to estimate the deviation of the first geometry parameter of the mirror device or for controlling a manufacturing step to modify the second geometry parameter, as explained referring to 21 of FIG. 2.

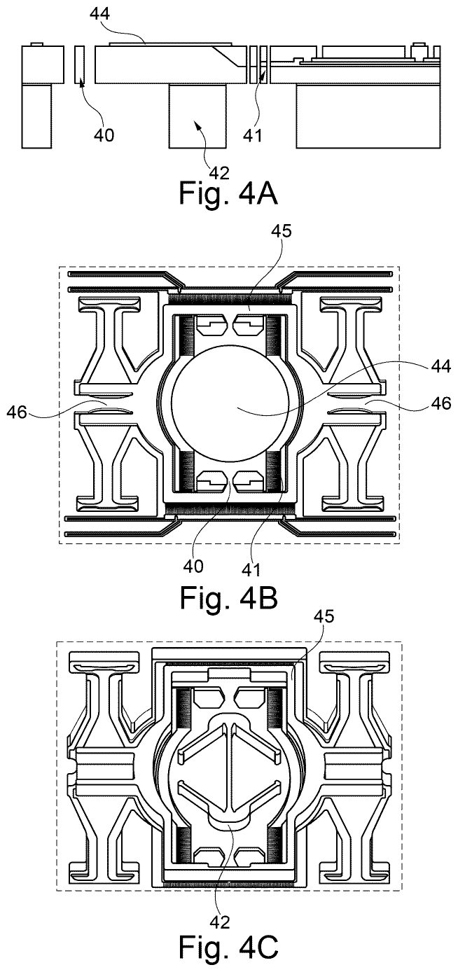

Examples for first and second geometry parameters and their use in implementing the method of FIG. 2 or the apparatus of FIG. 3 will now be explained in more detail. As an example microelectromechanical system mirror device for the following explanations, a mirror device having a gimbal structure as illustrated in FIGS. 4A, 4B and 4C is used. While this is a specific example, the principles and techniques such forth herein may also be applied to other mirror devices having a different structure from the one shown in FIGS. 4A, 4B and 4C.

FIG. 4A shows a schematic cross-sectional view of the mirror device, FIG. 4B shows a top view, and FIG. 4C shows a bottom view. The mirror device shown in FIGS. 4A-4C comprises a mirror 44, which may for example be made metal deposited on the structure or may comprise a stack of materials with different refractive indices so as to cause a reflection of light raise. Mirror 44 is suspended in a frame 45 rotatable about a first axis 40. On a back side of mirror 44, a mass structure 42 is formed, which influences a resonance frequency for rotation about axis 40 and an axis 46 via which frame 45 is suspended. Mass structure 42 may also serve for stiffening and supporting mirror 42. Furthermore, the mirror device comprises comb drive regions like regions 41 which are accessible by interconnects and serve to drive mirror 44 for rotation about axis 40 (or axis 44 for other comb structures). A first resonance frequency associated with a rotation about axis 40, inter alia due to the lower mass which has to be rotated, may be higher than a second resonance frequency associated with a rotation about axis 44.

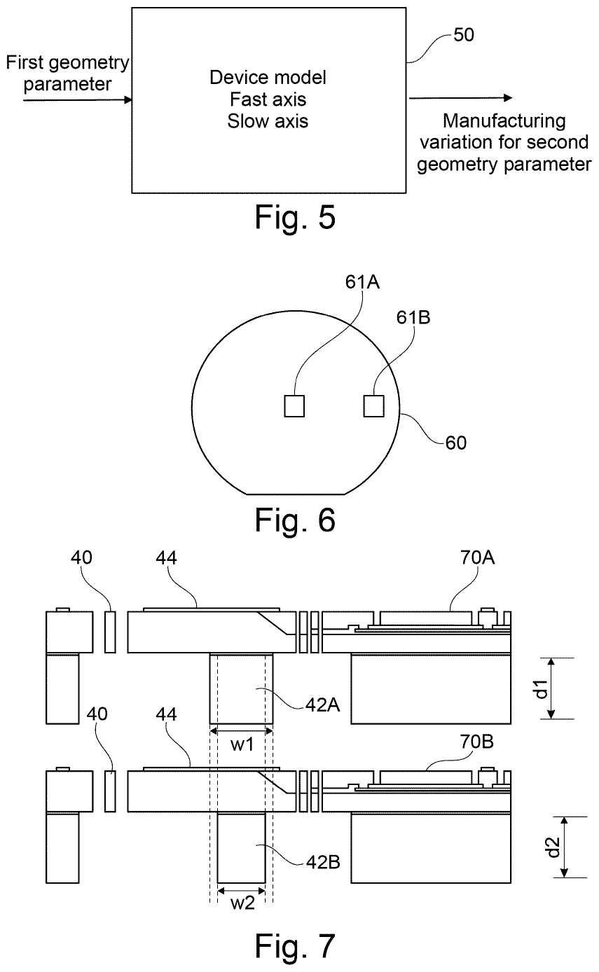

A mirror device as shown in FIGS. 4A-4C or also, more generically, in FIG. 1 may be modelled to determine how different geometry parameters influence the first resonance frequency, second resonance frequency and ration thereof. For example, such a model may take spring constants of axes 40, 44 depending on material thicknesses, width or structures, length of structures, masses to be rotated (for example thickness of mass 42, or frame 40, width of the structures etc.) and similar parameters into account. As illustrated in FIG. 5, for example the first geometry parameter and other parameters of the device may be provided to such a device model 50, and device model 50 may then determine a manufacturing variation for the second geometry parameter necessary to keep a change of the ratio between the first and second resonance frequencies within a given tolerance, for example 1%.

As already mentioned, a reference value for the first geometry parameter may for example be a reference value based on a design of the mirror device. It may also be a reference value compared to another mirror device. For example, process conditions may vary across a wafer where many mirror devices are manufactured. As an example, layer thicknesses may be lower or higher closer to the edge of a wafer than in the middle of the wafer. This is illustrated in FIG. 6.

FIG. 6 illustrates a wafer 60, for example silicon wafer, where for example at a first site close to the center of wafer 60 a first mirror device 61A is manufactured, and on a second site a second mirror device 61B is manufactured. These two mirror devices 61A, 61B serve only as examples, and a high number of such mirror devices may be manufactured on the same wafer on different sites. Due to process variations, the first geometry parameter may be different for mirror device 61B compared first mirror device 61A. The first geometry parameter for both mirror devices 61A, 61B may be measured, and the value for mirror device 61A may be taken as a reference value for second mirror device 61B.

Note that in some implementations, the measuring may then be on a reference wafer, and the values measured may be assumed for subsequentially produced wafers. In other implementations, the values may be measured directly during production (in-line measurement).

In other words, in this case the measurement is directly performed on the mirror device for which later the manufacturing step is modified, whereas in the former case the measurement is performed on a reference wafer, e.g., another mirror device, which for example has the same position on the wafer and is manufactured with the same parameters.

With techniques discussed herein, in some implementations it may be ensured that variations of the ratio between the first and second resonance frequencies for a set of mirror devices of the same type, for example manufactured on a same wafer as shown for mirror devices 61A, 61B, are below a predefined threshold, e.g., below 1%.

FIG. 7 illustrates first and second geometrical parameters for some implementations. FIG. 7 shows mirror devices 70A, 70B in cross-section corresponding to the view of FIG. 4A. Device 70A may for example be a device at a center of the wafer (for example mirror device 61A), whereas mirror device 70B may be a device closer to the edge of the wafer (for example mirror device 61B). In the example of FIG. 7, the estimation of the first geometry parameter indicated that a resonance frequency of mirror device 70B is too low taking mirror device 70A as a reference, or for example also that a resonance frequency of mirror device 70A needs to be decreased compared to mirror device 70B. For example, the first geometry parameter may be a layer thickness indicated as d1 for device 70A and d2 for device 70B. In this example, d1 may be lower than d2, which would result in a lower mass of structure 42A than of structure 42B. As a second geometry parameter, a width of structures 42A, 42B may be adjusted such that a width w1 of structure 42A is larger than a width w2 of structure 42B, which increases the mass of structure 42A compared to the mass of structure 42B and therefore at least partially can compensate the difference of layer thicknesses d1, d2.

The widths w1, w2 may be determined by a lithography step followed by an etching step. Therefore, for adjusting the widths w1, w2, a lithography step may be adjusted, for example by using a modified mask or also by changing an irradiation dose during lithography, where a higher dose may for example cause a wider region of photoresist to be irradiated and removed prior to etching, modifying structure sizes. Other parameters that may differ are parameters of ??? as the lithography step modifying the width W1, W2 is after a layer formation/deposition step determining thicknesses D1, D2, different layer thicknesses can be compensated by the following lithography.

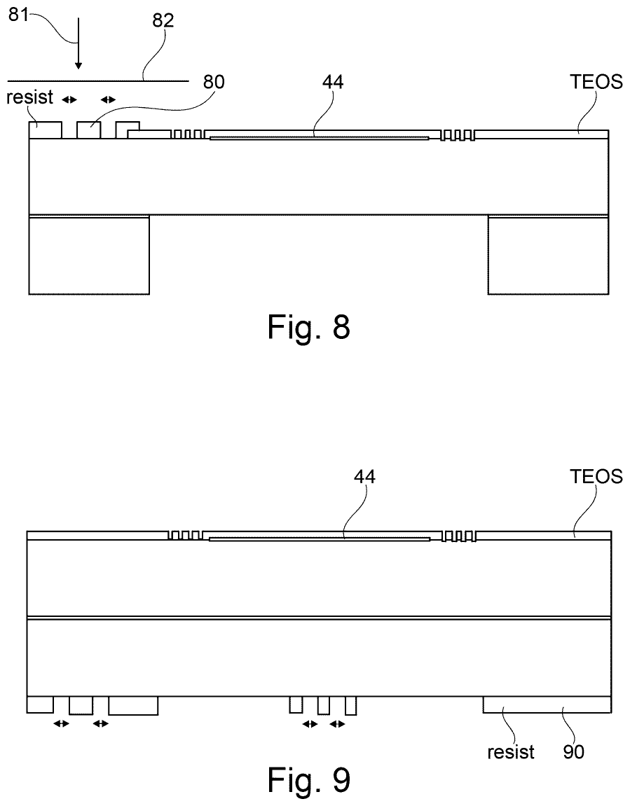

FIG. 8 shows an example where the manufacturing step which is modified is a release step for forming the gimbal structure shown in FIG. 4, for example forming a torsion bar serving as axis 40. A modification of the torsion bar structure may be made for changing a second geometry parameter. For forming the torsion bar, a photoresist 80 is provided on the structure, which is then exposed and partially removed to form a mask for material removal. Exposing photoresist 80 generally take place by irradiation 81 through a mask 82, which is only schematically shown in FIG. 8 and which mask for example may be placed essentially directly on the photoresist.

For adjusting the critical dimensions defined by the processed photoresist 80, two possibilities exist which may be combined or used independently from each other. On the one hand, mask 82 may be modified, e.g., the dimensions on mask 82 may be changed. This may for example be used for compensating systematic variations. For example, if it turns out that a first geometry parameter generally differs on the wafer from center to periphery, mask 82 may be modified such that a variation of the second geometry parameter, here the patterning for the torsion bar, varies accordingly from center to periphery to at least partially compensate the variation of the first geometry parameter with respect to the influence on the ratio between first resonance frequency and second resonance frequency.

Alternatively or additionally, a dose of irradiation 81 may be adjusted. A higher dose generally corresponds to wider exposed areas of photoresist 80, which also changes the structure sizes and hence the second geometry parameter. A variation of the dose may be more flexible than a change of the mask and may for example also be used to compensate individual variations during production.

FIG. 9 illustrates another example, where the modification occurs on the back side by modifying an exposure of photoresist 90, again either by using a corresponding mask (like mask 82) or by changing the dose of irradiation. In this way, for example, a width of mass 42 (for example width w1, w2) may be modified, or other structures on the back side, for example a mass of frame 45 of FIGS. 4B, 4C, may be modified. Both in FIGS. 8 and 9, double arrows illustrate the modified dimensions.

It should be noted that the modifications of the second geometry parameter illustrate in FIGS. 8 and 9 do not require additional processing steps, as existing processing steps are modified.

### ASPECTS

Some implementations are defined by the following aspects:
Aspect 1. A method for manufacturing a microelectromechanical system mirror device, wherein a mirror portion of the mirror device is rotatable about a first axis having an associated first resonance frequency and a second axis different from the first axis and having an associated second resonance frequency, comprising:
estimating a deviation of a first geometry parameter of the mirror device from a reference value,
adjusting a manufacturing step for the mirror device to modify a second geometry parameter of the mirror device different from the first geometry parameter such that a variation of a frequency ratio between the first resonance frequency and the second resonance frequency caused by the deviation of the first geometry parameter and the modifying of the second geometry parameter is below a predefined threshold.
Aspect 2. The method of aspect 1, further comprising determining the adjustment of the manufacturing step based on model of the mirror device which provides the variation of the frequency ratio depending on the first geometry parameter and the second geometry parameter.
Aspect 3. The method of aspect 1 or 2, wherein the mirror device is manufactured at a first site on a substrate, and wherein the reference value is a value of the first geometry parameter of a further mirror device manufactured at a second site on the substrate different from the first site.
Aspect 4. The method of any one of aspects 1 to 3, wherein estimating the deviation of the first geometry parameter comprises measuring a deviation of the first geometry parameter of another mirror device manufactured prior to the manufacturing of the mirror device using the same processing apparatus, and using the measured deviation as the estimated deviation.
Aspect 5. The method of any one of aspects 1 to 3, wherein estimating the deviation of the first geometry parameter comprises measuring the deviation of the first geometry parameter of the mirror device in a manufacturing stage prior to the manufacturing step.
Aspect 6. The method of any one of aspects 1 to 5, wherein the first geometry parameter comprises a layer thickness of a layer defining an inertia mass coupled to the mirror portion.
Aspect 7. The method of any one of aspects 1 to 6, wherein adjusting the manufacturing step comprises adjusting an exposure dose for lithography.
Aspect 8. The method of any one of aspects 1 to 7, wherein adjusting the manufacturing step comprises changing a geometry of a mask for lithography.
Aspect 9. The method of any one of aspects 1 to 8, wherein the second geometry parameter defines one of a suspension of the mirror portion associated with at least one of the first axis or second axis, a gimbal structure of the mirror device, a width of an inertial mass portion of the mirror device or a stiffening structure of the mirror device.
Aspect 10. The method of any one of aspects 1 to 9, wherein the predefined threshold is smaller than 1%.
Aspect 11. A manufacturing apparatus, comprising a processing chain configured to perform a plurality of processing steps for manufacturing a microelectromechanical system mirror device, wherein a mirror portion of the mirror device is rotatable about a first axis having an associated first resonance frequency and a second axis different from the first axis and having an associated second resonance frequency, and a process control device configure to estimate a deviation of a first geometry parameter of the mirror device from a reference value, and to adjust a manufacturing step for the mirror device to modify a second geometry parameter of the mirror device different from the first geometry parameter such that a variation of a frequency ratio between the first resonance frequency and the second resonance frequency caused by the deviation of the first geometry parameter and the modifying of the second geometry parameter is below a predefined threshold.
Aspect 12. The manufacturing apparatus of aspect 11, configured to perform the method of any one of aspects 1 to 11.
Aspect 13. A set of microelectromechanical system mirror devices of the same type wherein a mirror portion of each mirror device of the set is rotatable about a respective first axis having an associated first resonance frequency and a respective second axis different from the first axis and having an associated second resonance frequency, the set comprising a first mirror device and a second mirror device, wherein a first geometry parameter of the first mirror device differs from the first geometry parameter of the second mirror device by a first difference, wherein a second geometry parameter of the first mirror device differs from the second geometry parameter of the second mirror device by a second difference, wherein a difference between a first ratio between the first and second resonance frequencies of the first mirror device and a second ratio of the first and second resonance frequencies of the second mirror device caused by the first difference alone is above 1% and is compensated by the second difference to be below 1%.
Aspect 14. A wafer, comprising a first microelectromechanical system mirror device at a first site and a second microelectromechanical system mirror device at a second site, wherein a mirror portion of each of the first and second mirror devices is rotatable about a respective first axis having an associated first resonance frequency and a respective second axis different from the first axis and having an associated second resonance frequency, wherein a first geometry parameter of the first mirror device differs from the first geometry parameter of the second mirror device by a first difference, wherein a second geometry parameter of the first mirror device differs from the second geometry parameter of the second mirror device by a second difference, wherein a difference between a first ratio between the first and second resonance frequencies of the first mirror device and a second ratio of the first and second resonance frequencies of the second mirror device caused by the first difference alone is above 1% and is compensated by the second difference to be below 1%.

Although specific implementations have been illustrated and described herein, it will be appreciated by those of ordinary skill in the art that a variety of alternate and/or equivalent implementations may be substituted for the specific implementations shown and described without departing from the scope of the present implementation. This application is intended to cover any adaptations or variations of the specific implementations discussed herein. Therefore, it is intended that this implementation be limited only by the claims and the equivalents thereof.

1. A method for manufacturing a microelectromechanical system mirror device wherein a mirror portion of the microelectromechanical system mirror device is rotatable about a first axis having an associated first resonance frequency and a second axis different from the first axis and having an associated second resonance frequency, comprising:
estimating a deviation of a first geometry parameter of the microelectromechanical system mirror device from a reference value,
adjusting a manufacturing step for the microelectromechanical system mirror device to modify a second geometry parameter of the microelectromechanical system mirror device different from the first geometry parameter such that a variation of a frequency ratio between the associated first resonance frequency and the associated second resonance frequency caused by the deviation of the first geometry parameter and the modifying of the second geometry parameter below a predefined threshold.

2. The method of claim 1, further comprising:
determining an adjustment of the manufacturing step based on model of the microelectromechanical system mirror device which provides the variation of the frequency ratio depending on the first geometry parameter and the second geometry parameter.

3. The method of claim 1, wherein the microelectromechanical system mirror device is manufactured at a first site on a substrate, and wherein the reference value is a value of the first geometry parameter of a further microelectromechanical system mirror device manufactured at a second site on the substrate different from the first site.

4. The method of claim 1, wherein estimating the deviation of the first geometry parameter comprises measuring a deviation of the first geometry parameter of another microelectromechanical system mirror device manufactured prior to the manufacturing of the microelectromechanical system mirror device using a same processing apparatus, and using the measured deviation as the estimated deviation.

5. The method of claim 1, wherein estimating the deviation of the first geometry parameter comprises measuring the deviation of the first geometry parameter the microelectromechanical system mirror device in a manufacturing stage prior to the manufacturing step.

6. The method of claim 1, wherein the first geometry parameter comprises a layer thickness of a layer defining an inertia mass coupled to the mirror portion.

7. The method of claim 1, wherein adjusting the manufacturing step comprises adjusting an exposure dose for lithography.

8. The method of claim 1, wherein adjusting the manufacturing step comprises changing a geometry of a mask for lithography.

9. The method of claim 1, wherein the second geometry parameter defines one of a suspension of the mirror portion associated with at least one of the first axis or the second axis a gimbal structure of the microelectromechanical system mirror device, a width of an inertial mass portion of the microelectromechanical system mirror device or a stiffening structure of the microelectromechanical system mirror device.

10. The method of claim 1, wherein the predefined threshold is smaller than 1%.

11. A manufacturing apparatus, comprising:
a processing chain configured to perform a plurality of processing steps for manufacturing a microelectromechanical system mirror device wherein a mirror portion of the microelectromechanical system mirror device is rotatable about a first axis having an associated first resonance frequency and a second axis different from the first axis and having an associated second resonance frequency, and
a process control device configure to estimate a deviation of a first geometry parameter of the microelectromechanical system mirror device from a reference value, and to adjust a manufacturing step for the microelectromechanical system mirror device to modify a second geometry parameter of the microelectromechanical system mirror device different from the first geometry parameter such that a variation of a frequency ratio between the associated first resonance frequency and the associated second resonance frequency caused by the deviation of the first geometry parameter and the modifying of the second geometry parameter is below a predefined threshold.

12. (canceled)

13. A set of microelectromechanical system mirror devices of a same type, wherein a mirror portion of each microelectromechanical system mirror device of the set of microelectromechanical system mirror devices is rotatable about a respective first axis having an associated first resonance frequency and a respective second axis different from the respective first axis and having an associated second resonance frequency, the set of microelectromechanical system mirror devices comprising a first mirror device and a second mirror device,
wherein a first geometry parameter of the first mirror device differs from the first geometry parameter of the second mirror device by a first difference,
wherein a second geometry parameter of the first mirror device differs from the second geometry parameter of the second mirror device by a second difference,
wherein a difference between a first ratio between the associated first and the associated second resonance frequencies of the first mirror device and a second ratio of the associated first and the associated second resonance frequencies of the second mirror device caused by the first difference alone is above 1% and is compensated by the second difference to be below 1%.

14. A wafer, comprising:
a first microelectromechanical system mirror device at a first site and a second microelectromechanical system mirror device at a second site, wherein a mirror portion of each of the first and the second microelectromechanical system mirror devices is rotatable about a respective first axis having an associated first resonance frequency and a respective second axis different from the respective first axis and having an associated second resonance frequency,
wherein a first geometry parameter of the first microelectromechanical system mirror device differs from the first geometry parameter of the second microelectromechanical system mirror device by a first difference,
wherein a second geometry parameter of the first microelectromechanical system mirror device differs from the second geometry parameter of the second microelectromechanical system mirror device by a second difference,
wherein a difference between a first ratio between the associated first and the associated second resonance frequencies of the first microelectromechanical system mirror device and a second ratio of the associated first and the associated second resonance frequencies of the second microelectromechanical system mirror device caused by the first difference alone is above 1% and is compensated by the second difference to be below 1%.
